(19) United States
(12) Patent Application Publication
(10) Pub. No.: US 2025/0081861 A1
(43) Pub. Date: Mar. 6, 2025

(54) QUANTUM DEVICE AND MANUFACTURING METHOD

(71) Applicant: NEC Corporation, Minato-ku, Tokyo (JP)

(72) Inventors: Satoshi TSUKIYAMA, Tokyo (JP); Katsumi Kikuchi, Tokyo (JP)

(73) Assignee: NEC Corporation, Minato-ku, Tokyo (JP)

(21) Appl. No.: 18/752,850

(22) Filed: Jun. 25, 2024

(30) Foreign Application Priority Data
Jul. 3, 2023 (JP) 2023-109201

(51) Int. Cl. H10N 60/81

(52) U.S. Cl. CPC H10N 60/81

(57) ABSTRACT

A quantum device includes a quantum chip, a first interposer which faces the quantum chip, and bumps provided at locations between the first interposer and the quantum chip, the bumps including first bumps and second bumps, wherein the first bumps contain at least a superconducting material, and the second bumps are made of a different material from the first bumps.

### CROSS-REFERENCE TO RELATED APPLICATION

Priority is claimed on Japanese Patent Application No. 2023-109201, filed Jul. 3, 2023, the contents of which are incorporated herein by reference.

### BACKGROUND ART

The present disclosure relates to a quantum device and a manufacturing method.

U.S. Pat. No. 9,836,699 (hereinafter referred to as Patent Document 1) describes a configuration in which a quantum chip and a plurality of interposers are stacked and connected. More specifically, a configuration in which a quantum chip and an interposer or a plurality of interposers are bonded to each other by bonding balls is described.

### SUMMARY

In the configuration as disclosed in Patent Document 1, if the bonding balls between the quantum chip and the interposers are heated during the manufacturing process, the bonding balls may melt or soften, and thus the quantum chip may tilt with respect to the interposers, or they may become misaligned in the plane direction.

An example object of the present disclosure is to provide a quantum device and a manufacturing method of the same which can prevent a quantum chip from tilting or misaligning with respect to interposers when a quantum device on which the quantum chip is mounted is heated.

A quantum device according to one example aspect of the present disclosure includes: a quantum chip; a first interposer which faces the quantum chip; and bumps provided at locations between the first interposer and the quantum chip, the bumps including first bumps and second bumps, wherein the first bumps contain at least a superconducting material, and the second bumps are made of a different material from the first bumps.

A manufacturing method of a quantum device according to one example aspect of the present disclosure is a manufacturing method of a quantum device, the method: including: preparing a quantum chip; preparing a first interposer; and connecting the first interposer and the quantum chip at locations by first bumps containing a superconducting material and second bumps made of a material having a higher melting point than the first bumps.

A manufacturing method of a quantum device according to one example aspect of the present disclosure is a manufacturing method of a quantum device, the method including: connecting a first interposer and a quantum chip at locations; and connecting the first interposer and a second interposer at locations, the second interposer being configured to transmit and receive signals, wherein one of the connecting the first interposer and the quantum chip or the connecting the first interposer and the second interposer includes a first connection using low melting point bumps containing a superconducting material, wherein the other of the connecting the first interposer and the quantum chip or the connecting the first interposer and the second interposer includes a second connection using high melting point bumps containing a superconducting material having a higher melting point than the low melting point bumps, and wherein the first connection is performed after the second connection is performed.

According to the present disclosure, it is possible to prevent a quantum chip from being tilted or misaligned with respect to interposers when a quantum device on which the quantum chip is heated.

### BRIEF DESCRIPTION OF THE DRAWINGS

FIG. 1 is a cross-sectional view showing a quantum device according to some example embodiments of the present disclosure.

FIG. 2A is a cross-sectional view of a quantum device according to some example embodiments of the present disclosure.

FIG. 2B is a bottom view showing the arrangement of bumps according to some example embodiments of the present disclosure.

FIG. 3A is a cross-sectional view of a quantum device according to some example embodiments of the present disclosure.

FIG. 3B is a bottom view showing the arrangement of bumps according to some example embodiments of the present disclosure.

FIG. 4 is a layout diagram of bumps of a quantum device according to a first modified example of some example embodiments of the present disclosure.

FIG. 5 is a layout diagram of bumps of a quantum device according to a second modified example of some example embodiments of the present disclosure.

FIG. 6 is a layout diagram of bumps of a quantum device according to a third modified example of some example embodiments of the present disclosure.

FIG. 7 is a layout diagram of bumps of a quantum device according to a fourth modified example of some example embodiments of the present disclosure.

FIG. 8A is a cross-sectional view of a quantum device before heating in a method of manufacturing a quantum device according to some example embodiments of the present disclosure.

FIG. 8B is a cross-sectional view of the quantum device after heating in the method of manufacturing a quantum device according to some example embodiments of the present disclosure.

FIG. 9A is a cross-sectional view of a quantum device before heating in a method of manufacturing a quantum device according to some example embodiments of the present disclosure.

FIG. 9B is a cross-sectional view of the quantum device after heating in the method of manufacturing a quantum device according to some example embodiments of the present disclosure.

FIG. 10 is a cross-sectional view of a quantum device according to a method of manufacturing a quantum device according to some example embodiments of the present disclosure.

### EXAMPLE EMBODIMENT

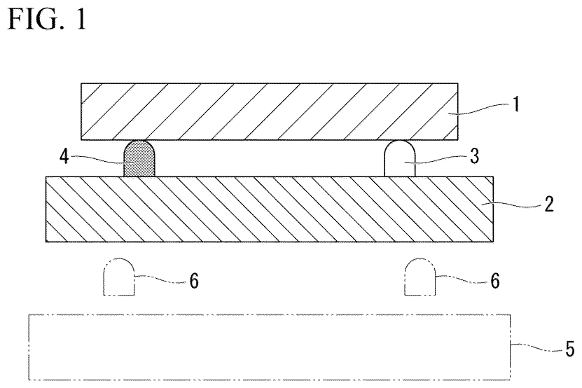

A quantum device according to some example embodiments of the present disclosure will be described with reference to FIG. 1.

The quantum device includes a quantum chip 1, a first interposer 2 on which the quantum chip 1 is mounted, and bumps provided at a plurality of locations between the first interposer 2 and the quantum chip 1, wherein the bumps include a first bump 3 and a second bump 4, the first bump 3 is at least partially made of a superconducting material, and the second bump 4 is made of a different material from the first bump 3.

According to the above configuration, the quantum chip 1 and the first interposer 2 can be electrically connected by the first and second bumps 3 and 4 and can be supported at a plurality of locations. Further, for the plurality of first and second bumps 3 and 4, for example, materials having different melting points can be used in combination.

Further, a method of manufacturing a quantum device according to some example embodiments of the present disclosure is a method of manufacturing a quantum device including the quantum chip 1 and the first interposer 2 on which the quantum chip 1 is mounted, the method including connecting the first interposer 2 and the quantum chip 1 at a plurality of locations using the first bump 3 made of a superconducting material and the second bump 4 made of a material having a higher melting point than the first bump 3.

According to the above configuration, after the quantum chip 1 is mounted on the first interposer 2, when the quantum chip 1 is further heated for some purpose, specifically, when the quantum chip 1 is heated in order to mount the first interposer 2 on a second interposer 5, for example, the quantum chip 1 can be supported at a predetermined position on the first interposer 2 by not melting either the first bump 3 or the second bump 4 which has a higher melting point. In the configuration described in Patent Document 1, since a plurality of interposers are stacked, when the quantum chip is bonded to an interposer and then further bonded to another interposer, the bonding balls between the quantum chip and the interposer melt or soften due to heating during bonding to the other interposer, and thus the quantum chip may tilt with respect to the interposer or they may become misaligned in the plane direction.

Further, a method for manufacturing a quantum device according to some example embodiments of the present disclosure is a method of manufacturing a quantum device including a quantum chip 1, a first interposer 2 on which the quantum chip 1 is mounted, and a second interposer 5 on which the first interposer 2 is mounted and which is configured to transmit and receive signals, the method including a first process of connecting the first interposer 2 and the quantum chip 1 at a plurality of locations, and a second process of connecting the first interposer 2 and the second interposer 5 at a plurality of locations, wherein, by using bumps having different melting points; low melting point bumps 3 and 4 made of a superconducting material; and high melting point bumps 6 made of a superconducting material having a higher melting point than the low melting point bumps 3 and 4, connection using the low melting point bumps 3 and 4 is performed after connection using the high melting point bumps 6 in the first process and the second process.

According to the above configuration, after connection using the high melting point bumps is performed, connection using the low melting point bumps is performed according to heating at a lower temperature than the temperature for the previous connection, and thus the connection performed later is not damaged by the connection using the high melting point bumps used for connection performed in the previous process, and components of the connected quantum device are not misaligned.

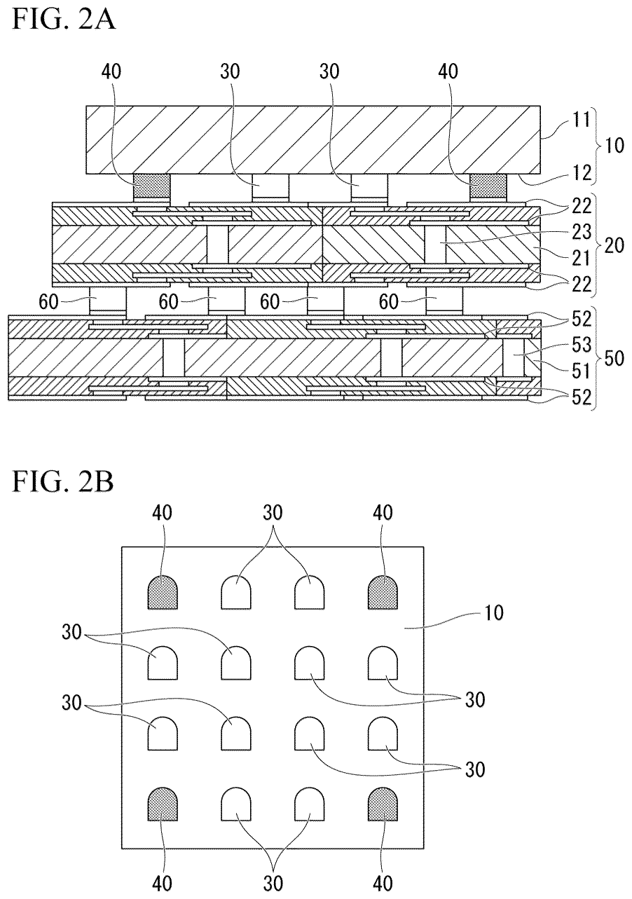

FIG. 2A and FIG. 2B show some example embodiments of the present disclosure.

Reference numeral 10 denotes a quantum chip that performs quantum computing.

The quantum computing refers to a function of manipulating data using quantum mechanical phenomena using quantum bits, and the quantum chip 10 has a configuration in which a conductive wiring layer in a predetermined circuit pattern is provided on the lower surface 12 of a substrate 11 made of silicon, for example. It is desirable that the conductive wiring layer be made of a superconducting material.

The conductive wiring layer is made of niobium (Nb), niobium nitride, aluminum (Al), indium (In), lead (Pb), tin (Sn), rhenium (Re), palladium (Pd), titanium (Ti), titanium nitride, tantalum (Ta), or an alloy containing any of materials. Further, in the present example embodiments, as a normal conductive material used for conductive wiring other than the conductive wiring connected to the quantum chip, for example, copper (Cu), silver (Ag), gold (Au), platinum (Pt), or an alloy containing any of these materials is used.

The quantum chip 10 is mounted on a first interposer 20, and these are connected by a plurality of first bumps 30 and second bumps 40.

The first interposer 20 includes an interposer substrate 21, an interposer wiring layer 22 provided on the front surface (surface on the side of the quantum chip 10) and the back surface (opposite surface), or inside of the interposer substrate 21, and a connecting conductor 23 that penetrates the interposer substrate 21 to electrically connect the front, back, or internal interposer wiring layers 22.

The interposer substrate 21 is, for example, a silicon substrate. Further, it is desirable that the front surface of the interposer substrate 21 be covered with a silicon oxide film (SiO2, TEOS film, or the like). Further, the interposer wiring layer 22 may be made of a superconducting material such as niobium (Nb). In this case, the interposer wiring layer 22 may contain the same superconducting material as the conductive wiring of the quantum chip 10 or may contain a different superconducting material. Further, the interposer wiring layer 22 may contain a normal conductive material such as copper (Cu).

The interposer wiring layer 22 may include not only a simple conductor circuit but also a quantum circuit. For example, a magnetic field application circuit (not shown) for applying a magnetic field to a resonator (loop circuit) may be formed in the interposer wiring layer 22. Further, a readout circuit (not shown) for reading quantum state information from a resonator (conductive member) may be formed in the interposer wiring layer 22. Further, a ground electrode circuit may be formed in the interposer wiring layer 22. That is, a ground electrode circuit may be formed in the interposer wiring layer 22 as a quantum circuit. In this manner, when a quantum circuit is formed in the interposer wiring layer 22, the first interposer 20 functions as a quantum interposer. Further, an oscillator (not shown) can be configured by at least the resonator and the magnetic field application circuit.

For the first bumps 30, a superconducting material connected to a quantum chip wiring layer on the lower surface 12 of the substrate 11 and having a lower melting point than the material used for the second bumps is used. The second bumps 40 are made of a superconducting material having a higher melting point than that of the first bumps 30. The difference in melting point between the high melting point bumps and the low melting point bumps is 10° C. or more, preferably 30° C. or more, and more preferably 50° C. or more.

Examples of materials that can be used for the first bumps 30 and the second bumps 40 include indium (In), tin (Sn), aluminum (Al), niobium (Nb), bismuth (Bi), yttrium. (Y), lead (Pb), and alloys thereof.

Among the above materials, it is desirable that the first bumps 30 and the second bumps 40 be made of materials having a combination of melting points described in the above example embodiments.

Furthermore, it is more desirable that the first bumps 30 contain at least indium (In), and the second bumps 40 contain at least a metal other than indium (In). For example, it is desirable that the material of the first bumps 30 be indium (In), and the material of the second bumps 40 be an alloy of indium (In) and another metal (for example, an alloy of In and Al), or a metal that does not contain In (for example, Sn, Al, Nb, Bi, Y, or Pb).

Further, in some example embodiments of the present disclosure, the second bumps 40 are disposed at portions of four corners of a matrix of 4 rows and 4 columns as a whole, and the first bumps 30 are disposed between the second bumps 40 (at positions other than the four corners), as shown in FIG. 2B. The bumps between the second bumps 40 at the four corners may also be made of a high melting point material (all bumps in the first and fourth rows and the first and fourth columns as well as the bumps at the four corners, that is, all bumps at the perimeter) and used as the high melting point second bumps 40, and the inner region surrounded by these second bumps 40 may be used as the low melting point first bumps 30.

Furthermore, the first interposer 20 is mounted on the second interposer 50.

The second interposer 50 is electrically connected to the first interposer 20, and includes an interposer substrate 51, an interposer wiring layer 52 provided on the front surface (the surface on the side of the first interposer 20), the back surface (the opposite surface), or inside of the interposer substrate 51, and a connecting conductor 53 that electrically connects the front, back, and internal interposer wiring layers 52. As in the first interposer 20, the interposer substrate 51 is a silicon substrate, for example, and is preferably covered with a silicon oxide film (SiO2, TEOS film, or the like). Further, the interposer wiring layer 52 may be made of a superconducting material such as niobium (Nb), for example. In this case, the interposer wiring layer 52 may contain the same superconducting material as the quantum chip 10 or the conductor wiring of the first interposer 20 or may contain a different superconducting material. Further, the interposer wiring layer 52 may contain a normal conductive material such as copper (Cu).

The second interposer 50 and the first interposer 20 are electrically connected by a plurality of third bumps 60. The third bumps 60 are made of a superconducting material that is the same as the first bumps 30 or has a lower melting point than the second bumps 40. Further, the plurality of third bumps 60 connect the interposer wiring layer 22 on the lower surface of the first interposer 20 and the interposer wiring layer 52 on the upper surface of the second interposer 50 and are disposed in a matrix of 4 rows and 4 columns, for example, in accordance with the positions and numbers of the connection electrodes.

Examples of materials that can be used for the third bumps 60 include indium (In), tin (Sn), aluminum (Al), niobium (Nb), bismuth (Bi), yttrium (Y), lead (Pb), and alloys thereof.

Among the aforementioned materials, a superconducting material that is the same as that of the first bumps 30 or has a lower melting point than the second bumps 40 of the above-described example embodiments is used. The melting point may be lower than that of the first bumps 30.

Furthermore, it is more preferable that the third bumps 60 contain at least indium (In), and the second bumps 40 contain at least a metal other than indium (In).

Here, examples of combinations of materials constituting the first bumps 30, the second bumps 40, and the third bumps 60 include combinations shown in Table 1 below.

TABLE 1

| First bumps | Second bumps | Third bumps |
|---|---|---|
| In | Sn | In |
| Sn | Al | In |
| In | Al | Sn |

The quantum device having the above configuration is assembled by two processes: a first process of disposing the quantum chip 10 on the first interposer 20 with the first bumps 30 and the second bumps 40 disposed at predetermined positions interposed therebetween, and melting the first bumps 30 and the second bumps 40 by performing heating from the side of the quantum chip 10 or the side of the first interposer 20 to electrically and mechanically connect the quantum chip 10 and the first interposer 20; and a second process of disposing the first interposer 20 on the second interposer 50 with the third bumps 60 disposed at predetermined positions interposed therebetween, and melting the third bumps 60 by performing heating from the side of the second interposer 50 or the side of the first interposer 20 to electrically and mechanically connect the first interposer 20 and the second interposer 50.

Here, at the time of heating the third bumps 60 for mounting on the second interposer 50, the melting point of the third bumps 60 is lower than the melting point of the second bumps 40, and thus the four corners of the quantum chip 10 can be supported by the second bumps 40 having a high melting point even if the first bumps 30 melts or softens due to heating of the third bumps 60, and therefore misalignment and tilting of the quantum chip 10 with respect to the first interposer 20, and even occurrence of poor connection can be prevented.

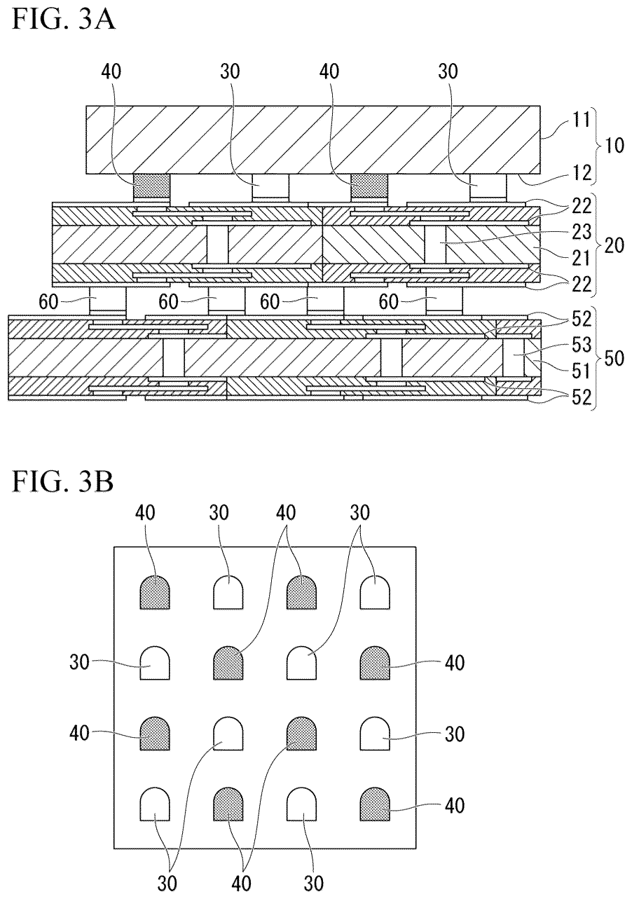

FIG. 3A and FIG. 3B illustrate some example embodiments of the present disclosure. In FIG. 3A and FIG. 3B, the same components as those in FIG. 2A and FIG. 2B are denoted by the same reference numerals and description thereof is simplified.

A quantum device according to some example embodiments of the present disclosure has a configuration in which the quantum chip 10 is disposed on the first interposer 20, they are electrically and mechanically connected by a plurality of first bumps 30 and a plurality of second bumps having a higher melting point than that of the first bumps 30 which are interposed therebetween, the first interposer 20 is disposed on the second interposer 50, and they are electrically and mechanically connected by a plurality of third bumps 60 interposed therebetween.

As shown in FIG. 3B, the first bumps 30 and the second bumps 40 are disposed in a matrix of 4 rows and 4 columns as a whole, and the first bumps 30 and the second bumps 40 are disposed alternately. As a result, the first bumps 30 having a low melting point are disposed between the second bumps 40 having a high melting point.

The quantum device according to some example embodiments of the present disclosure can be assembled by the two processes: the first process and the second process step described in the quantum device according to the above-described example embodiments.

In some example embodiments of the present disclosure, when the first interposer 20 on which the quantum chip 10 is mounted is disposed on the second interposer 50 and heated, even if the first bumps 30 melts or softens between the quantum chip 10 and the first interposer 20, the second bumps 40 having a high melting point are disposed on both sides of the first bumps 30, and thus the second bumps 40 can maintain the shape thereof without melting or softening during the second heating process and can support the quantum chip 10. Accordingly, misalignment, tilting, and poor connection between the quantum chip 10 and the first interposer 20 can be prevented.

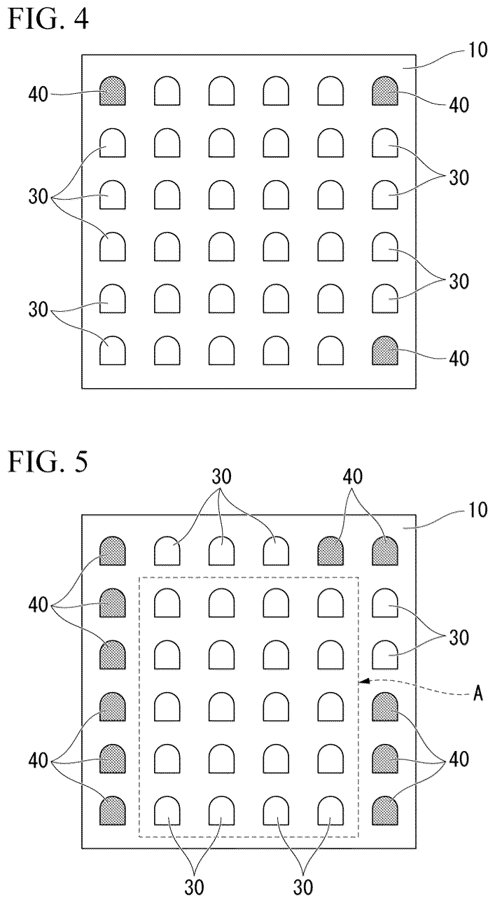

FIG. 4 shows a first modified example of the arrangement of the first bumps 30 and the second bumps 40.

The first bumps 30 and the second bumps 40 of the first modified example are arranged in a matrix of 6 rows and 6 columns as a whole, and three of the four corners of this matrix correspond to the second bumps 40, the remaining corner corresponds to the first bumps 30.

That is, according to the arrangement shown in FIG. 4, since the quantum chip 10 can be supported at three points (minimum support points required to identify the plane that supports the quantum chip 10) by the second bumps 40 disposed at the three corners, even if the first pumps 30 melts or softens in the process through which the first interposer 20 is disposed on the second interposer 50 and re-heated, the quantum chip 10 can be supported at three points by the second bumps 40 having a higher melting point than that of the first bumps 30, and thus misalignment, tilting, or poor connection of the quantum chip 10 due to attachment to the second interposer 50 can be prevented.

FIG. 5 shows a second modified example of the arrangement of the first bumps 30 and the second bumps 40.

The first bumps 30 and the second bumps 40 of the second modified example are arranged in a matrix of 6 rows and 6 columns as a whole, and in this matrix, the first bumps 30 having a low melting point are disposed in a range overlapping an area surrounded by a broken line A in FIG. 5, specifically, an area where the quantum circuit of the quantum chip 10 is provided on the first interposer 20 in plain view (in general, the quantum circuit is not disposed on the entire surface of the quantum chip and is formed in an area inside from the surface), the second bumps 40 having a higher melting point are disposed outside the area surrounded by the broken line A, and the first bumps 30 are disposed in a portion of an area while ensuring the regularity in arrangement in which the first bumps 30 are interposed between the second bumps 40 even if the area is outside the area surrounded by the broken line A.

That is, according to the arrangement shown in FIG. 5, the area of connection with the quantum circuit of the quantum chip 10, which requires a high degree of superconductivity, is connected by the first bumps 30 having a low melting point, and the second bumps 40 having a high melting point are disposed outside the area. Although indium (In) is preferable as the material for the bumps connected to the quantum circuit from the viewpoint of superconductivity, indium has a relatively low melting point. However, the second bumps 40 having a high melting point are disposed on the outside thereof.

According to this arrangement, since the quantum chip 10 can be supported by the second bumps 40 having a high melting point disposed on the outside, the second bumps 40 having a higher melting point than that of the first bumps 30 can prevent misalignment, tilting, or poor connection of the quantum chip 10 that occurs when the first interposer 20 is attached to the second interposer 50 even if the first bumps 30 softens or melts when the first interposer 20 is disposed on the second interposer 50 and heated.

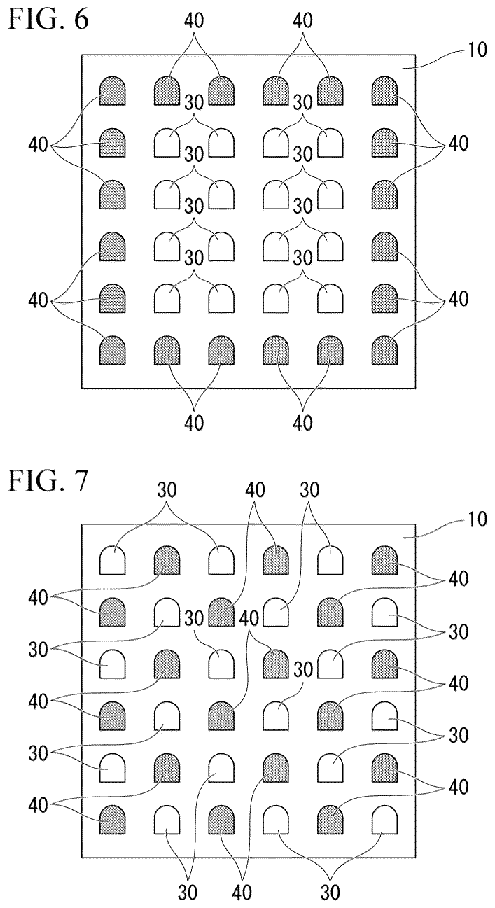

FIG. 6 shows a third modified example of the arrangement of the first bumps 30 and the second bumps 40.

The first bumps 30 and the second bumps 40 of the third modified example are arranged in a matrix of 6 rows and 6 columns as a whole, the second bumps 40 are disposed at 20 locations surrounding the outer periphery of this matrix, and the first bumps 30 are disposed at 16 locations surrounded by the second bumps 40.

In the third modified example, even if the first bumps 30 softens or melts due to heating of the third bumps 60 accompanied by mounting of the second interposer 50, the second bumps 40 having a high melting point disposed around the first bumps 30 can uniformly support the entire peripheral portion of the quantum chip 10, thereby preventing the quantum chip 10 from tilting, misalignment, or poor connection.

FIG. 7 shows a fourth modified example of the arrangement of the first bumps 30 and the second bumps 40.

The first bumps 30 and the second bumps 40 of the fourth modified example are arranged in a matrix of 6 rows and 6 columns as a whole, and the first bumps 30 having a relatively low melting point and the second bumps 40 having a relatively high melting point are disposed alternately.

In the fourth modified example, since the first bumps 30 are interposed between the second bumps 40, even if one first bump 30 softens or melts due to heating of the third bumps 60 accompanied by mounting of the second interposer 50, the second bumps 40 on both sides thereof can support the quantum chip 10, and thus the quantum chip 10 can be prevented from tilting, misalignment, or poor connection.

As a fifth modified example of the constituent material of the bumps described above, fourth bumps that do not connect the quantum computing circuit of the quantum chip 10 and the circuit on the first interposer side may be added to the second bump 40, or this bump portion may be used in place of some thereof. That is, by using a material having a higher melting point than the first and third bumps 30 and 60 for the fourth bumps, similarly to the second bumps 40, the fourth bumps may supports the quantum chip 10 without melting or softening during heating. In addition to the superconducting material used for the second bumps 40, a normal conductive material such as copper (Cu), silver (Ag), gold (Au), platinum (Pt), palladium (Pd), or an alloy containing any of these materials may also be used for the fourth bumps. Furthermore, at least one of the metal pattern on the side of the quantum chip 10 and the metal pattern on the side of the first interposer 20 connected by the fourth bumps is not connected to the circuit (is electrically insulated and isolated from the circuit). Accordingly, no current flows through the fourth bumps, and thus the quantum circuit of the quantum chip 10 is not electrically affected. It is preferable that the fourth bumps be not connected to at least the circuit on the side of the quantum chip 10. It is preferable that the fourth bumps be disposed outside the first bumps as in the first modified example, the second modified example, or the third modified example.

The fifth modified example can also be assembled by the two processes, the first process and the second processes described in the quantum device of the above-described embodiments.

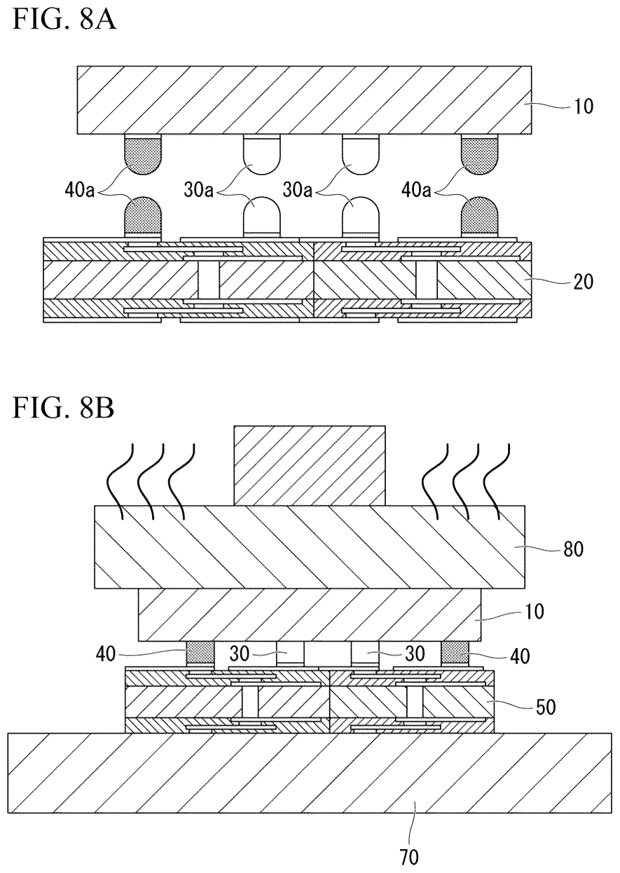

FIG. 8A and FIG. 8B illustrate a method of manufacturing the quantum device according to some example embodiments of the present disclosure. FIG. 8A shows a state before mounting, and FIG. 8B shows a state during mounting.

In the method of manufacturing the quantum device shown in FIG. 8A and FIG. 8B, first, first bump pieces 30a that become parts of the first bumps 30 and are provided on the side of the quantum chip 10 and first bump pieces 30a provided on the side of the first interposer 20 and having the same composition and the same arrangement are made to face each other, as shown in FIG. 8A, and similarly, second bump pieces 40a that become parts of the second bumps 40 and second bump pieces 40a provided on the side of the first interposer 20 and having the same composition and the same arrangement are made to face each other and aligned.

Subsequently, as shown in FIG. 8B, when the quantum chip 10 is heated while being pressed onto the first interposer 20 on a surface plate 70 using a heating press machine 80, the first bump pieces 30a facing each other melt and diffuse to be fused, thereby forming the first bumps 30. Further, the second bump pieces 40a facing each other melt and diffuse to be fused, thereby forming the second bumps 40 made of a material having a higher melting point than that of the first bumps 30.

After waiting for the first bumps 30 and the second bumps 40 to cool and solidify in the state shown in FIG. 8B, the quantum chip 10 is mounted on the first interposer 20. Furthermore, a quantum device can be manufactured by placing the first interposer 20 on which the quantum chip 10 is mounted on the second interposer 50 and heating and pressurizing between the surface plate 70 and the heating press machine 80.

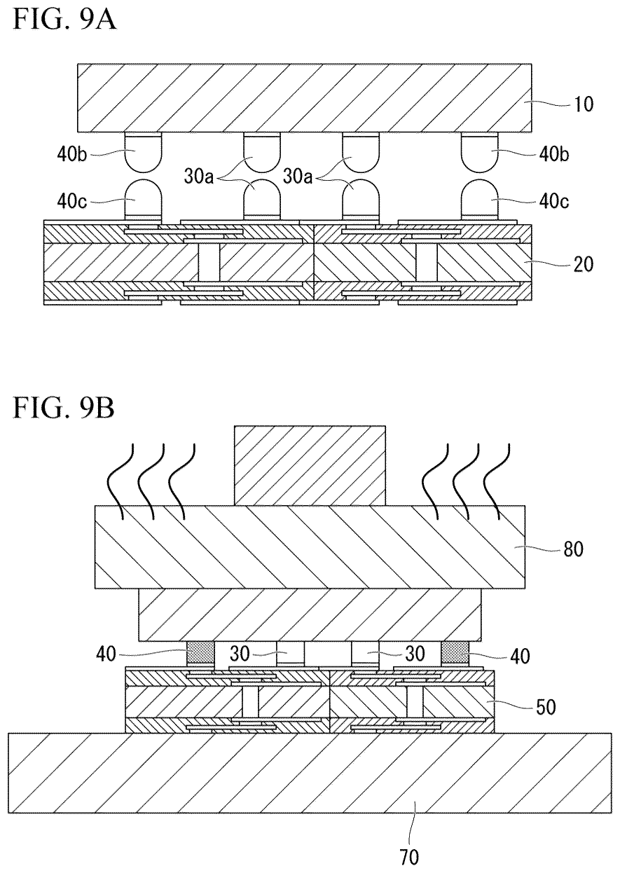

FIG. 9A and FIG. 9B show a method of manufacturing a quantum device according to some example embodiments. FIG. 9A shows a state before mounting, and FIG. 9B shows a state during mounting.

In the process of manufacturing a quantum device shown in FIG. 9A and FIG. 9B, first, first bump pieces 30a that become parts of the first bumps 30 and are provided on the side of the quantum chip 10 and first bump pieces 30a provided on the side of the first interposer 20 and having the same composition and the same arrangement are made to face each other, as shown in FIG. 9A, and similarly, second bump pieces 40b that become parts of the second bumps 40 and second bump pieces 40c provided on the side of the first interposer 20 and having the same arrangement are made to face each other and aligned.

Here, the second bump pieces 40b and 40c are formed of different single metals (or alloys with different compositions) and have a characteristic that the melting point thereof increases when they are fused by melting and diffusion.

Subsequently, as shown in FIG. 9B, when the quantum chip 10 is heated while being pressed onto the first interposer 20 on the surface plate 70 by the heating press machine 80, the first bump pieces 30a facing each other melt and diffuse to be fused, thereby forming the first bumps 30. Further, the second bump pieces 40b and 40c facing each other melt and diffuse to be fused, thereby forming the second bumps 40 having a higher melting point than that of the first bumps.

After waiting for the first bumps 30 and the second bumps 40 to cool and solidify in the state shown in FIG. 9B, the quantum chip 10 is mounted on the first interposer 20. Furthermore, a quantum device can be manufactured by placing the first interposer 20 on which the quantum chip 10 is mounted on the second interposer 50 and heating and pressurizing between the surface plate 70 and the heating press machine 80.

By using a similar method, the first bump pieces on the side of the quantum chip 10 and the first bump pieces on the side of the first interposer 20 may be made of different metals (or alloys) and melt and diffuse together to decrease the melting point.

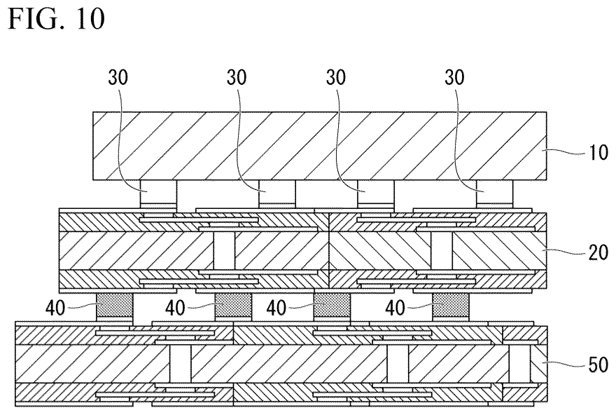

FIG. 10 illustrates a method of manufacturing a quantum device according to some example embodiments of the present disclosure.

In these example embodiments, the quantum chip 10 and the first interposer 20 are connected by a plurality of first bumps 30, and the first interposer 20 and the second interposer 50 are connected by the second bumps 40 having a higher melting point than that of the first bumps 30.

In these example embodiments, a quantum device can be manufacturing by placing and mounting the first interposer 20 on the second interposer 50 using the second bumps 40 having a high melting point, and then mounting the quantum chip 10 on the first interposer 20 using the first bumps 30.

Here, since the melting point of the second bumps 40 is higher than that of the first bumps 30, the second bumps 40 do not soften and melt by heating in the process of mounting the quantum chip 10 on the first interposer 20, and thus tilting, misalignment, or poor connection between the first interposer 20 and the second interposer 50 can be prevented.

Although it is desirable to use the first bumps 30 having a low melting point for connection between the quantum chip 10 and the first interposer 20 from the standpoint of superconducting performance, contrary to the example of FIG. 10, the second bumps 40 having a high melting point may be used between the quantum chip 10 and the first interposer 20, and the first bumps 30 may be provided between the first interposer 20 and the second interposer 50 to mount the quantum chip 10 on the first interposer 20 first.

The number and arrangement of quantum chips and interposers are not limited to the example embodiments described above, and the number and arrangement, constituent materials, and combinations thereof of bumps are not limited to the example embodiments described above.

Although some example embodiments according to the present disclosure have been described above in detail with reference to the drawings, specific configurations are not limited to these example embodiments, and design changes without departing from the gist of the present disclosure may also be included. Each example embodiment can be combined with other example embodiments as appropriate.

In addition, although an example in which the problem that the mounting state of the quantum chip is damaged during heating at the time of bonding between the second interposer and the first interposer is solved has been described in the above example embodiments, the present disclosure can also be implemented to solve the problem that the mounting state of the quantum chip is damaged when a heating process is required for some purpose after the quantum chip is mounted on the first interposer in manufacturing a quantum device.

Although part or all of the above example embodiments can also be described as in the following supplementary notes, the example embodiments are not limited to the aspects specified in the supplementary notes.

### (Supplementary Note 1)

A quantum device including:
a quantum chip;
a first interposer which faces the quantum chip; and
bumps provided at locations between the first interposer and the quantum chip, the bumps including first bumps and second bumps,
wherein the first bumps contain at least a superconducting material, and the second bumps are made of a different material from the first bumps.

### (Supplementary Note 2)

The quantum device according to supplementary note 1, wherein the second bumps contain a material having a higher melting point than the first bumps.

### (Supplementary Note 3)

The quantum device according to supplementary note 1 or 2, wherein the first bumps are provided in a first area where a circuit of the quantum chip is connected to the first bumps, the circuit containing a superconducting material, and the second bumps are provided in a second area other than the first area.

### (Supplementary Note 4)

The quantum device according to any one of supplementary notes 1 to 3, wherein the first bumps are disposed inside the second bumps.

### (Supplementary Note 5)

The quantum device according to any one of supplementary notes 1 to 4, wherein the first bumps are provided in a first area near a center of the quantum chip, and the second bumps are provided in a second area farther from the center of the quantum chip than the first area are.

### (Supplementary Note 6)

The quantum device according to any one of supplementary notes 1 to 5, wherein at least three of the second bumps are disposed outside of an area where the first bumps are present.

### (Supplementary Note 7)

The quantum device according to any one of supplementary notes 1 to 6, wherein the first bumps and the second bumps are arranged in a matrix.

### (Supplementary Note 8)

The quantum device according to any one of supplementary notes 1 to 7, further including a second interposer provided on a surface of the first interposer opposite to a surface of the first interposer which faces the quantum chip,
wherein third bumps have a lower melting point than the second bumps and are provided between the first interposer and the second interposer.

### (Supplementary Note 9)

The quantum device according to any one of supplementary notes 1 to 8, wherein the first bumps contain at least indium, and the second bumps contain at least a material other than indium.

### (Supplementary Note 10)

A manufacturing method of a quantum device, the method comprising:
preparing a quantum chip;
preparing a first interposer; and
connecting the first interposer and the quantum chip at locations by first bumps containing a superconducting material and second bumps made of a material having a higher melting point than the first bumps.

### (Supplementary Note 11)

The manufacturing method of a quantum device according to supplementary note 10, further including:
disposing a second interposer on a surface of the first interposer opposite to a surface of the first interposer to which the first and second bumps are connected; and
connecting the second interposer and the first interposer at locations by third bumps having a lower melting point than the second bumps.

### (Supplementary Note 12)

The manufacturing method of a quantum device according to supplementary note 11, wherein at least either of the second or third bumps are formed by mutually diffusing first bump metal pieces and second bump metal pieces, the first bump metal pieces being provided on a first conductor, the second bump metal pieces being provided on a second conductor, the first and second conductors being connected to each other by the at least either of the second or third bumps.

### (Supplementary Note 13)

A manufacturing method of a quantum device, the method including:
connecting a first interposer and a quantum chip at locations; and
connecting the first interposer and a second interposer at locations, the second interposer being configured to transmit and receive signals,
wherein one of the connecting the first interposer and the quantum chip or the connecting the first interposer and the second interposer includes a first connection using low melting point bumps containing a superconducting material,
wherein the other of the connecting the first interposer and the quantum chip or the connecting the first interposer and the second interposer includes a second connection using high melting point bumps containing a superconducting material having a higher melting point than the low melting point bumps, and
wherein the first connection is performed after the second connection is performed.

According to the quantum device and manufacturing method of the present disclosure, it is possible to prevent the quantum chip from tilting or misaligning with respect to the interposer when the quantum device on which the quantum chip is mounted is heated.

What is claimed is:

1. A quantum device comprising:
a quantum chip;
a first interposer which faces the quantum chip; and
bumps provided at locations between the first interposer and the quantum chip, the bumps including first bumps and second bumps,
wherein the first bumps contain at least a superconducting material, and the second bumps are made of a different material from the first bumps.

2. The quantum device according to claim 1, wherein the second bumps contain a material having a higher melting point than the first bumps.

3. The quantum device according to claim 1, wherein the first bumps are provided in a first area where a circuit of the quantum chip is connected to the first bumps, the circuit containing a superconducting material, and the second bumps are provided in a second area other than the first area.

4. The quantum device according to claim 1, wherein the first bumps are disposed inside the second bumps.

5. The quantum device according to claim 1, wherein the first bumps are provided in a first area near a center of the quantum chip, and the second bumps are provided in a second area farther from the center of the quantum chip than the first area are.

6. The quantum device according to claim 1, wherein at least three of the second bumps are disposed outside of an area where the first bumps are present.

7. The quantum device according to claim 1, wherein the first bumps and the second bumps are arranged in a matrix.

8. The quantum device according to claim 1, further comprising a second interposer provided on a surface of the first interposer opposite to a surface of the first interposer which faces the quantum chip,
wherein third bumps have a lower melting point than the second bumps and are provided between the first interposer and the second interposer.

9. The quantum device according to claim 1, wherein the first bumps contain at least indium, and the second bumps contain at least a material other than indium.

10. A manufacturing method of a quantum device, the method comprising:
preparing a quantum chip;
preparing a first interposer; and
connecting the first interposer and the quantum chip at locations by first bumps containing a superconducting material and second bumps made of a material having a higher melting point than the first bumps.

11. The manufacturing method of a quantum device according to claim 10, further comprising:
disposing a second interposer on a surface of the first interposer opposite to a surface of the first interposer to which the first and second bumps are connected; and
connecting the second interposer and the first interposer at locations by third bumps having a lower melting point than the second bumps.

12. The manufacturing method of a quantum device according to claim 11, wherein at least either of the second or third bumps are formed by mutually diffusing first bump metal pieces and second bump metal pieces, the first bump metal pieces being provided on a first conductor, the second bump metal pieces being provided on a second conductor, the first and second conductors being connected to each other by the at least either of the second or third bumps.

13. A manufacturing method of a quantum device, the method comprising:
connecting a first interposer and a quantum chip at locations; and
connecting the first interposer and a second interposer at locations, the second interposer being configured to transmit and receive signals,
wherein one of the connecting the first interposer and the quantum chip or the connecting the first interposer and the second interposer includes a first connection using low melting point bumps containing a superconducting material,
wherein the other of the connecting the first interposer and the quantum chip or the connecting the first interposer and the second interposer includes a second connection using high melting point bumps containing a superconducting material having a higher melting point than the low melting point bumps, and
wherein the first connection is performed after the second connection is performed.
